(19) United States
(12) Patent Application Publication
(10) Pub. No.: US 2021/0050279 A1
(43) Pub. Date: Feb. 18, 2021

(54) COMPOSITE FILMS

(71) Applicant: Hewlett-Packard Development Company, L.P., Spring, TX (US)

(72) Inventors: Kuan-Ting Wu, Taipei City (TW); Chi Hao Chang, Taipei City (TW); Chien-Ting Lin, Taipei City (TW)

(73) Assignee: Hewlett-Packard Development Company, L.P., Spring, TX (US)

(21) Appl. No.: 16/980,518

(22) PCT Filed: May 7, 2018
(86) PCT No.: PCT/US2018/031312

§ 371 Date: Sep. 14, 2020

(51) Int. Cl. H01L 23/373; B32B 9/00; B32B 9/04; B32B 7/12

(52) U.S. Cl. CPC H01L 23/3735; B32B 9/007; B32B 2457/00; B32B 9/045; B32B 7/12; B32B 9/041

(57) ABSTRACT

The present subject matter relates to composite films for heat dissipation. In an example implementation of the present subject matter, a composite film for heat dissipation comprises a conductive material layer for thermal conduction of heat; and a polymer layer disposed over the conductive material layer to provide insulation from the heat.

### BACKGROUND

Electronic devices utilize multiple electronic components to provide various functionalities. Such electronic components generate heat during their operation, and quick and effective dissipation of the generated heat ensures effective performance of the electronic device and avoids failure of the electronic components.

### BRIEF DESCRIPTION OF DRAWINGS

The following detailed description references the drawings, wherein:

FIG. 1 illustrates a composite film for heat dissipation, according to an example implementation of the present subject matter;

FIG. 2 illustrates a composite film for heat dissipation, according to an example implementation of the present subject matter;

FIG. 3 illustrates a composite film for heat dissipation; according to an example implementation of the present subject matter;

FIG. 4 illustrates a composite film for heat dissipation, according to an example implementation of the present subject matter;

FIG. 5 illustrates a composite film for heat dissipation, according to an example implementation of the present subject matter;

FIG. 6 illustrates a composite film for heat dissipation; according to an example implementation of the present subject matter;

FIG. 7 illustrates a composite film for heat dissipation, according to an example implementation of the present subject matter;

FIG. 8 illustrates a composite film for heat dissipation, according to an example implementation of the present subject matter;

FIG. 9 illustrates a composite film for heat dissipation, according to an example implementation of the present subject matter;

FIG. 10 illustrates a composite film for heat dissipation, according to an example implementation of the present subject matter;

FIG. 11 illustrates an electronic device implementing a composite film, according to an example implementation of the present subject matter;

FIG. 12 illustrates a housing implementing a composite film for heat dissipation, according to an example implementation of the present subject matter.

### DETAILED DESCRIPTION

Generally, electronic devices include multiple electronic components packed in a housing. With the advancements in technology, size of the electronic devices is continuously decreasing while the number of electronic components in the electronic device is increasing. Thus, in the housing of the electronic device, space available for heat dissipation and associated components thereof is limited. In such a scenario, it is challenging to provide adequate heat dissipation within the electronic device so as to efficiently manage thermal energy and/or heat generated by various electronic components, as well as minimize the overall size of the device.

Generally known components for the dissipation of heat, i.e., heat dissipaters, may include components such as heat sinks, vapor chambers, heat pipes, heat dissipating films, and other types of components suitable for the transfer of thermal energy. Heat dissipating films, for example, include a combination of thin conductive layers. Some heat dissipaters utilize an aerogel layer along with the conductive layers to also provide heat dissipation along with heat insulation between electronic components of the electronic device. The combination of conductive layers and aerogel layers dissipates heat generated by the electronic components, and also insulates heated electronic components from other electronic components of the electronic device. However, the aerogel layer utilized in formation of heat dissipaters generally includes silica. Silica-based heat dissipating films are generally rigid, thereby making it difficult to mold such heat dissipating films as per the shape and size of an electronic component. Further, compression of silica based heat dissipating films causes disintegration of the aerogel layer, thereby causing the heat dissipating film to lose its insulation properties.

According to examples of the present subject matter, heat dissipating composite films are described. In an example implementation of the present subject matter, composite films comprising conductive material layers, such as copper and graphene layers, and polymer aerogel layers are described. The composite films may be used in electronic devices to dissipate heat generated by various electronic components of the electronic device. In an example implementation of the present subject matter, a composite film includes at least one conductive or conducting material layer along with at least one polymer aerogel layer.

In an example implementation of the present subject matter, the polymer aerogel layer of the composite film includes materials such as phenolics, polyurethanes, polyimides, and polyamides. The use of such materials provide flexibility to the polymer aerogel layer, and also allows the polymer aerogel layer to be compressed under pressure without disintegration. In an example implementation of the present subject matter, while the composite film may dissipate heat generated by electronic components, the composite film may also provide insulation from hot spot areas of the electronic components. That is, while the polymer aerogel layer in the composite film of the present subject matter may shield components of the electronic device and users from hot spot areas by providing heat insulation, the conducting material layers may provide effective heat dissipation.

In an example implementation of the present subject matter, a conductive material layer may be disposed over a heat source, such as an electronic component of the electronic device. The conductive material layer may include any thermal conductor that allows effective heat dissipation, such as graphite, graphene, copper, gold, silver, aluminium, and synthetic graphite.

Further, the polymer aerogel layer may be disposed over the conductive material layer. The polymer aerogel layer may act as a thermal insulator, thereby protecting components of the electronic device from heat. In an example implementation of the present subject matter, the polymer aerogel layer may be formed of phenolics, polyurethanes, polyimides, and polyamides, which may provide flexibility and effective heat insulation to the polymer aerogel layer.

The use of the described composite film may allow for effective heat dissipation and reduce hot spot areas in electronic devices. Thus, use of the described composite film may extend the lifetime of electronic devices such as Smartphones, Liquid Crystal Display (LCD) devices, Light Emitting Diode (LED) displays, central processing units (CPU), or other types of electronic devices. Due to effective dissipation of heat, the use of the described composite film may also reduce risk of battery fire or explosion due to overheating of electronic devices or components thereof.

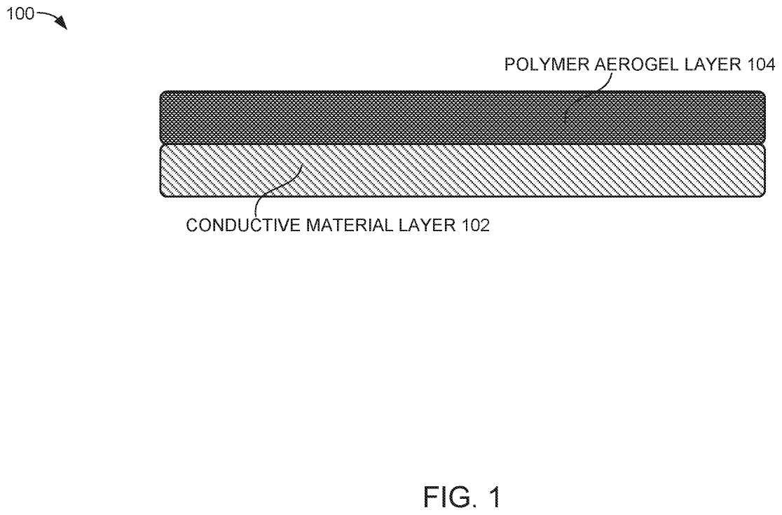

The above described aspects of the present subject matter are further described with reference to explanation of the FIGS. 1-12. It would be noted that the description and the figures merely illustrate the principles of the present subject matter along with examples described herein, and would not be construed as a limitation to the present subject matter. It is thus understood that various arrangements may be devised that, although not explicitly described or shown herein, embody the principles of the present subject matter. Moreover, all statements herein reciting principles, aspects, and implementations of the present subject matter, as well as specific examples thereof, are intended to encompass equivalents thereof.

FIG. 1 illustrates a composite film 100, according to an example implementation of the present subject matter. The composite film 100 may include at least one conductive material layer 102 along with at least one polymer aerogel layer 104. In an example of the present subject matter, a conductive material layer 102 and a polymer aerogel layer 104 is disposed such that at least one surface of the conductive material layer 102 abuts at least one surface of the polymer aerogel layer 104.

It would be noted that due to the heat generated by an electronic component, hot spots may be created on a surface of the electronic component. Such hot spots may radiate heat which may either cause damage to nearby components, or may also cause discomfort or even skin burns to users of the electronic device. Therefore, the described composite film 100 may dissipate heat from the electronic component and may also shield other components and users of the electronic device from hot spots created on the surface of the electronic component.

To this end, the conductive material layer 102 of the composite film 100 may absorb and dissipate heat from a heat source such as an electronic component of an electronic device, while the polymer aerogel layer 104 may act as an insulator, thereby preventing heat transfer to other components of the electronic device.

In an example of the present subject matter, the conductive material layer 102 may include materials with thermal conductivity higher than 100 watts per meter-kelvin (w/m-K), at room temperature. For example, the conductive material layer 102 may be formed of materials including, but not limited to, copper, silver, gold, aluminum, graphene, natural graphite, synthetic graphite, combinations thereof, or other materials that may have thermal conductivity higher than 100 W/m-K.

In examples of the present subject matter, composite film 100 may either include a single conductive material layer 102 of a conductive material, such as copper, silver, gold, aluminum, graphene, natural graphite, and synthetic graphite, or may include a combination of layers of the conductive material layer 102. Further, in examples, where multiple conductive material layers 102 are utilized, thickness of each conductive material layer 102 may vary depending upon application of the composite film 100. For example, the composite film 100 may include three conductive material layers 102, including a metal layer sandwiched between two layers of graphene. In such an example, the graphene layer may have a thickness of about 5 to 50 nanometers (nm) while the metal layer may have a thickness of about 0.01 to 0.2 millimeters (mm).

In an example of the present subject matter, the polymer aerogel layer 104 may include polymer aerogels with thermal conductivity lower than 1 watts per meter-kelvin, at room temperature. For example, the polymer aerogel layer 104 may be formed of material including, but not limited to, phenolics, polyurethanes, polyimides, polyamides, and combinations thereof, which may provide flexibility to the polymer aerogel layer and effective heat insulation with thermal conductivity of less than 1 W/m-K.

In an example of the present subject matter, the polymer aerogel layer 104 is flexible and is about 80% to 95% porous. Further, the polymer aerogel layer may have a surface area of about 200 to 600 meters squared per gram (m²/g). Furthermore, the polymer aerogel layer 104 may also have density of about 0.1 to 0.5 grams per cubic centimeter (g/cc) with mesopores of about 2 to 50 nm in diameter, and micropores of diameter less than 2 nm. Further, thickness of each polymer aerogel layer 104 may be of about 0.05 to 2.0 mm.

It would be noted that the thickness of each of the conductive material layer 102 and the polymer aerogel layer 104 may be varied depending upon the application of the composite film 100, and availability of heat dissipation space in the electronic device.

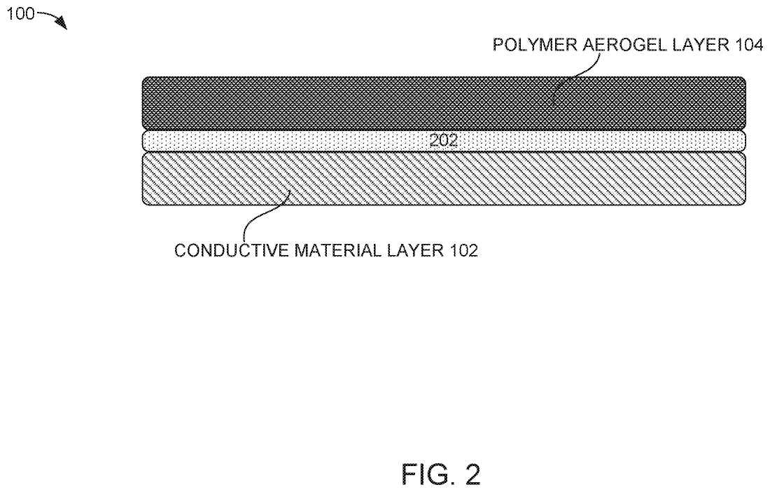

Referring to FIG. 2, composite film 100 may further include an adhesive layer 202 disposed between the conductive material layer 102 and the polymer aerogel layer 104. The adhesive layer 202 may attach the conductive material layer 102 and the polymer aerogel layer 104 to each other. In an example of the present subject matter, the adhesive layer 202 is formed of materials including, but not limited to, isocyanate based polymers, such as Polymeric diphenylmethane diisocyanate (PMDI), urethanes, and urea; epoxies, acrylics, ethylene-vinyl acetate (EVA) copolymers, polyamides, polyolefins, styrene copolymers, polyester, and polyurethane. Further, in some example, the adhesive layer 202 may also include hot melt adhesives and rubber-based adhesives.

In an example of the present subject matter, the adhesive layer 202 may be disposed between the conductive material layer 102 and the polymer aerogel layer 104 for adhesion. Therefore, the amount of adhesive included in the adhesive layer 202 may vary based on the material of the conductive material layer 102 and the polymer aerogel layer 104. Thus, the thickness of the adhesive layer 202 may be about 1 to 50 micrometers (μm).

It would be noted that the adhesive layer 202 is disposed to provide adhesion between the conductive material layer 102 and the polymer aerogel layer 104. Therefore, in conditions where the conductive material layer 102 and the polymer aerogel layer 104 are self-adhesive with respect to each other, the adhesive layer 202 may be considered to be a part of either the conductive material layer 102 and/or the polymer aerogel layer 104.

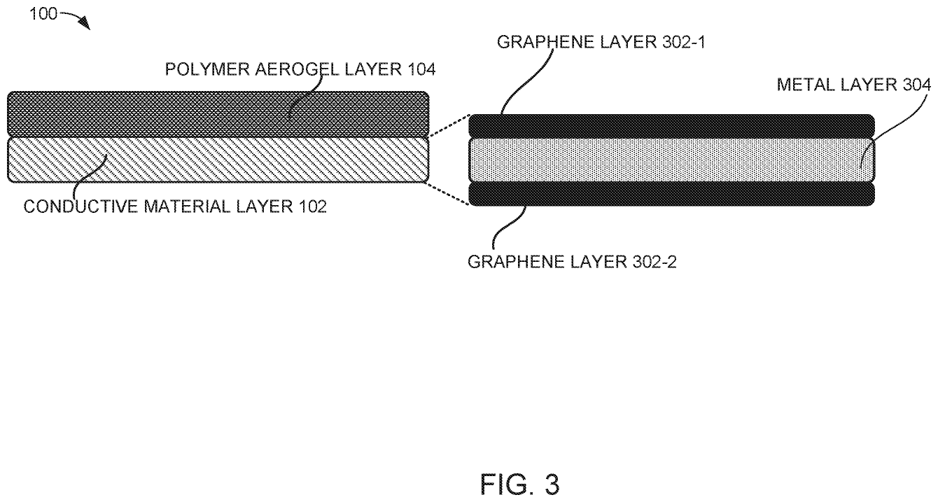

In an example of the present subject matter, the composite film 100 may include multiple conductive material layers 102. For example, FIG. 3 depicts an arrangement where the composite film 100 includes three conductive material layers 102, according to example of the present subject matter. In an example of the present subject matter, the conductive material layer 102 includes two graphene layers 302-1 and 302-2, and a metal layer 304. Further, the polymer aerogel layer 104 is disposed over the graphene layer 302-1. The metal layer 304 may be formed of materials including, but not limited to, copper, silver, gold, aluminum, and alloys thereof. The polymer aerogel layer 104 may be formed of materials including, but not limited to phenolics, polyurethanes, polyimides, and polyamides.

It would thus be noted that the composite film 100 may include four layers, including three conductive material layers and the polymer aerogel layer 104. In an example of the present subject matter, the inclusion of three conductive material layers 102 may provide effective heat dissipation. Further, since graphene has a thermal conductivity of about 3000 W/m-K at room temperature, use of graphene layers 302-1 and 302-2 may provide effective thermal conduction and radiation for heat dissipation.

In an example of the present subject matter, each of the graphene layer 302-1 and 302-2 may have a thickness of about 5 to 50 nm, and the thickness of the metal layer 304 may be about 0.01 to 0.2 mm. Further, the polymer aerogel layer 104 may have a thickness of about 0.05 to 2 mm.

In another example of the present subject matter, the graphene layers 302-1 and 302-2 may also be replaced with natural of synthetic graphite layers, depending on the application and usage of the composite film 100. Thus, it would be noted that the composite film 100 may include one or multiple conductive material layers 102 and a polymer aerogel layer 104.

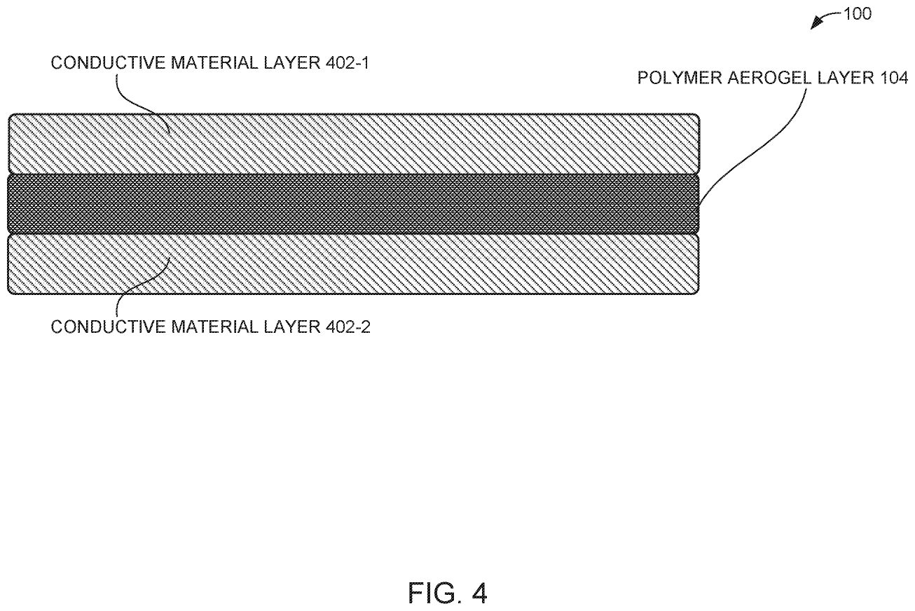

FIG. 4 depicts the composite film 100, according to an example of the present subject matter. The composite film 100, as depicted in FIG. 4, may include the polymer aerogel layer 104 sandwiched between two conductive material layers 402-1 and 402-2. Each of the two conductive material layers 402-1 and 402-2 may be formed of materials including, but not limited to, copper, silver, gold, aluminum, graphene, natural graphite, synthetic graphite, and/or a combination thereof. For example, the conductive material layers 402-1 and 402-2 may be graphene layers or metal layers disposed over the polymer aerogel layer 104.

As described earlier, the polymer aerogel layer 104 may be formed of materials including, but not limited to phenolics, polyurethanes, polyimides, polyamides, and combinations thereof. Further, in an example of the present subject matter, the polymer aerogel layer 104 may be respectively attached to the conductive material layers 402-1 and 402-2 by an adhesive layer or layers (not shown).

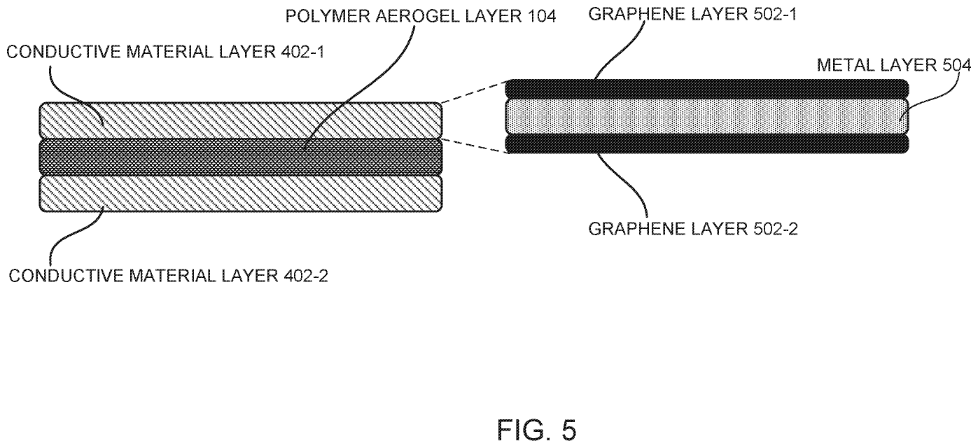

In an example of the present subject matter, either of the conductive material layer 402-1 and 402-2 may include a combination of multiple conductive material layers to provide effective dissipation of heat. For example, the conductive material layer 402-1 may include a combination of three conductive material layers, as depicted in FIG. 5.

Referring now to FIG. 5, in an example, the conductive material layer 402-1 may include a first graphene layer 502-1 and a second graphene layer 502-2, and a metal layer 504. Further, the polymer aerogel layer 104 is disposed under the second graphene layer 502-2, such that the polymer aerogel layer 104 is sandwiched between the second graphene layer 502-2 and the conductive material layer 402-2. Therefore, the composite film 100 may include five layers, including the first graphene layer 502-1, the metal layer 504, the second graphene layer 502-2, the polymer aerogel layer 104 and the conductive material layer 402-2.

The metal layer 504 may be formed of materials including, but not limited to, copper, silver, gold, aluminum, and alloys thereof. As described earlier, the polymer aerogel layer 104 may be formed of materials including, but not limited to phenolics, polyurethanes, polyimides, and polyamides. In an example of the present subject matter, each of the first graphene layer 502-1 and the second graphene layer 502-2 may have a thickness of about 5 to 50 nm, and the thickness of the metal layer 504 may be of about 0.01 to 0.2 mm. Further, the polymer aerogel layer 104 may have a thickness of about 0.05 to 2 mm.

In another example of the present subject matter, the first graphene layer 502-1 and the second graphene layer 502-2 may also be replaced with natural or synthetic graphite layers, depending on the application and usage of the composite film 100. It would be appreciated that the conductive material layer 402-2 may also include multiple conductive material layers, such as a third graphene layer and a fourth graphene layer, similar to that of the conductive material layer 402-1. However, such an example has not been depicted in FIG. 5 and has not been further explained for the sake of brevity.

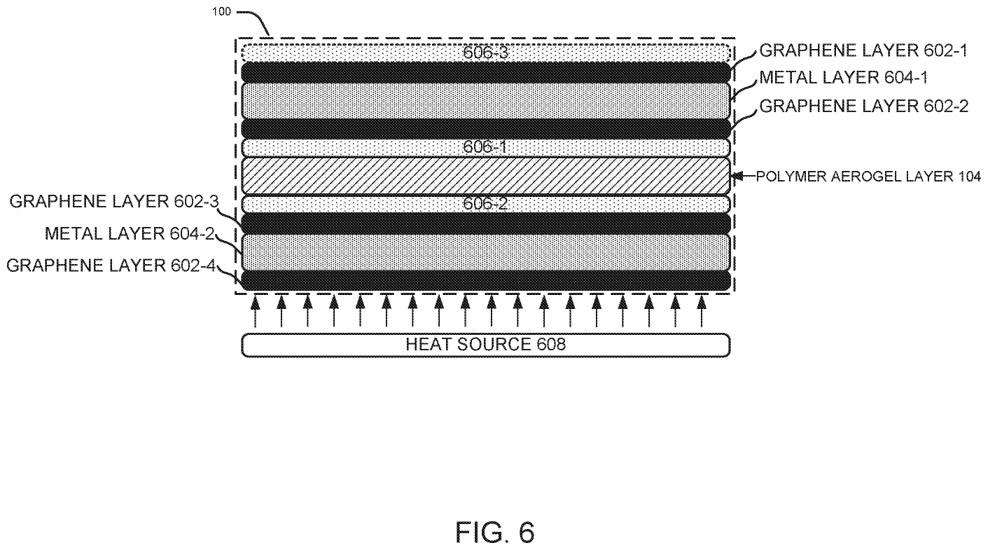

FIG. 6 depicts a composite film 100, according to an example of the present subject matter. The composite film 100, as depicted in FIG. 6, includes the polymer aerogel layer 104 along with multiple conductive material layers disposed on either side of the polymer aerogel layer 104. The conductive material layers may include graphene layers 602-1, 602-2, 602-3, and 602-4 and metal layers 604-1 and 604-2, such that the metal layer 604-1 is sandwiched between the graphene layer 602-1 and the graphene layer 602-2, and the metal layer 604-2 is sandwiched between the graphene layer 602-3 and the graphene layer 602-4. Further, different layers in the composite film 100 are disposed such that the polymer aerogel layer 104 is disposed between the graphene layer 602-2 and the graphene layer 602-3.

In an example of the present subject matter, the graphene layer 602-2 and the graphene layer 602-3 are attached to the polymer aerogel layer 104 through adhesive layers 606-1 and 606-2, respectively. Further, the composite film 100, also includes an adhesive layer 606-3 disposed on the graphene layer 602-1. The adhesive layer 606-3 may allow the composite film 100 to be pasted onto different surfaces of electronic devices or components thereof. For example, the composite film 100 may be pasted on an inner surface of a housing of an electronic device, and over an electronic component, such as a microprocessor. The adhesive layer 606-3 may allow the composite film to be pasted onto any surface of the housing.

In operation, the heat generated by a heat source 608, such as the microprocessor of the electronic device, is absorbed by the graphene layer 602-4. The heat absorbed by the graphene layer 602-4 may be transferred to other layers, such as the metal layer 604-2 and the graphene layer 602-3, and dissipated to the surroundings. Further, the polymer aerogel layer 104 may act as a shield to the heat generated by the heat source 608. The polymer aerogel layer 104 may avoid transfer of heat to other layers and avoid any damage due to excessive heat and created hot spots. Further, any heat transferred by the polymer aerogel layer 104 may be further dissipated by the graphene layer 602-2, the metal layer 604-1, and the graphene layer 602-1, Thus, the described composite film 100 may dissipate heat generated by the heat source 608, and may also prevent damage from any created hot spots.

In another example of the present subject matter, some or all of the graphene layers 602-1, 602-2, 602-3, and 602-4 may be replaced with natural or synthetic graphite layers, depending on the application and usage of the composite film 100. Further, the arrangement of the graphene layers 602-1, 602-2, 602-3, and 602-4, and the metal layers 604-1 and 604-2 may also be varied in different examples of the present subject matter.

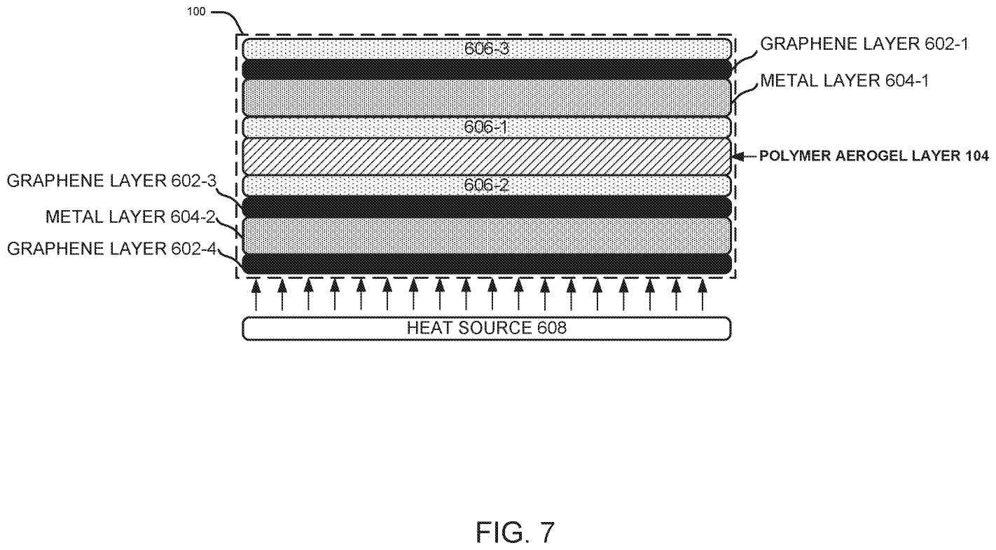

Other arrangements of various conductive material layers 102, such as the graphene layers 602-1, 602-2, 602-3, and 602-4, the metal layers 604-1 and 604-2, the adhesive layers 606-1, 606-2, 606-3, and the polymer aerogel layer 104 to form the composite film 100 are depicted in FIG. 7 to FIG. 10.

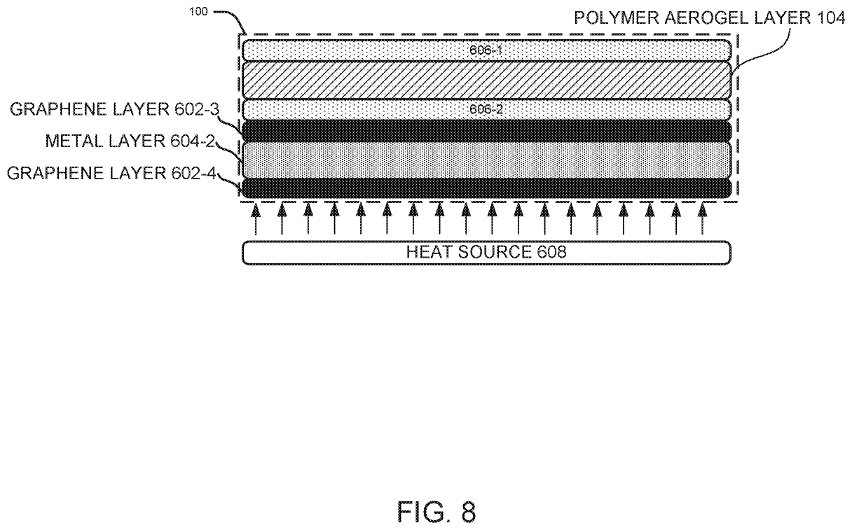

FIG. 7 and FIG. 8 illustrate different arrangements of the conductive material layers disposed over the polymer aerogel layer 104, according to examples of the present subject matter. In FIG. 7, the composite film 100 may include a graphene layers 602-1, 602-3, and 602-4 and metal layers 604-1 and 604-2, such that the metal layer 604-1 is sandwiched between the graphene layer 602-1 and the polymer aerogel layer 104, and the metal layer 604-2 is sandwiched between the graphene layer 602-3 and the graphene layer 602-4. Thus, it would be noted that the arrangement, as depicted in FIG. 7 does not include the graphene layer 602-2, such that the polymer aerogel layer is sandwiched between the metal layer 604-1 and the graphene layer 602-3. Further, as described earlier, the polymer aerogel layer 104 may be attached to different layers through adhesive layers. For example, the polymer aerogel layer 104 may be attached to the metal layer 604-1 with the adhesive layer 606-1. Similarly, the polymer aerogel layer 104 may be attached to the graphene layer 602-3 through the adhesive layer 606-2. Furthermore, the composite film 100 may also include the adhesive layer 606-3 to allow the composite film 100 to be pasted or adhered onto different surfaces of electronic device.

In FIG. 8, the conductive material layers disposed over the polymer aerogel layer 104 are removed, such that the composite film 100 includes the polymer aerogel layer 104, the graphene layers 602-3 and 602-4, and the metal layer 604-2. In such an arrangement, the metal layer 604-2 is sandwiched between the graphene layer 602-3 and the graphene layer 602-4, and the polymer aerogel layer 104 is disposed over the graphene layer 602-3. In an example, the adhesive layer 606-2 is disposed between the polymer aerogel layer 104 and the graphene layer 602-3 to provide adhesion. Further, the adhesive layer 606-1 disposed over the polymer aerogel layer 104 may allow the composite film 100 to be pasted onto different surfaces of electronic device.

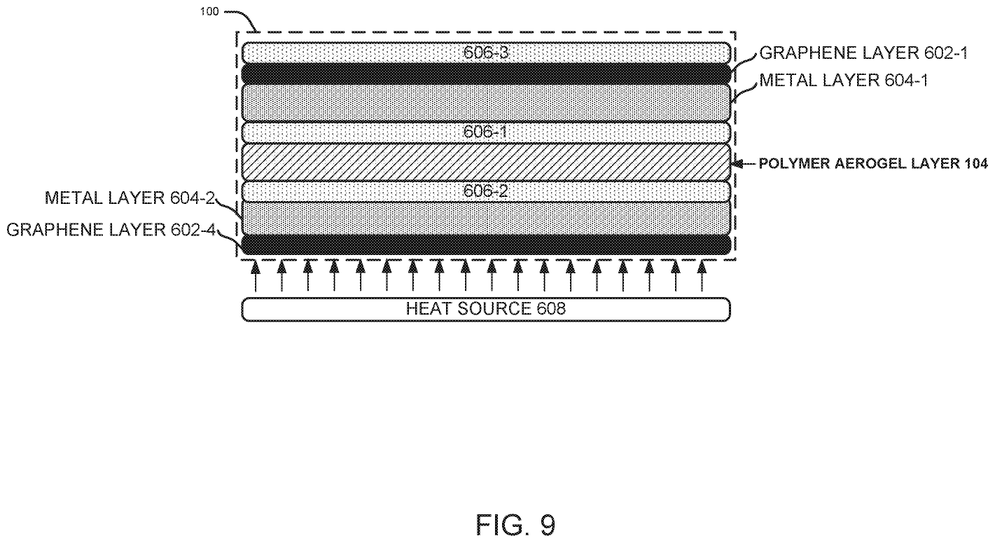

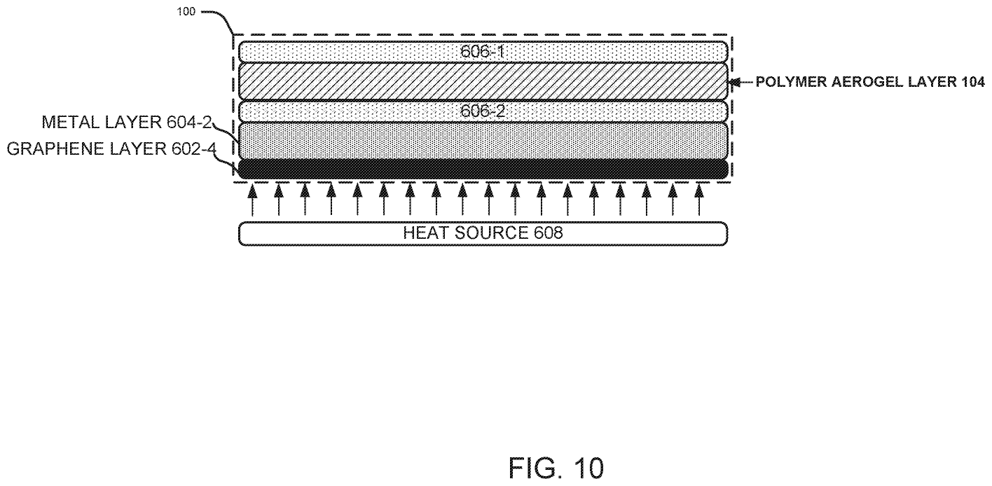

FIG. 9 and FIG. 10 depict arrangements of different conductive material layers in the composite film 100, according to different examples of the present subject matter. FIG. 9 depicts an arrangement of the composite film 100 where the polymer aerogel layer 104 is sandwiched between the metal layer 604-1 and the metal layer 604-2. That is, the graphene layers 602-2 and 602-3 have been removed from the arrangement depicted in FIG. 6. It would be noted that the arrangement of other layers, such as the graphene layer 602-1, 602-4, the metal layers 604-1 and 604-2, and the adhesive layers 606-1, 606-2, and 606-3 may absorb heat from the heat source 606 and effectively dissipate it to the surroundings. Further, the polymer aerogel layer 104 may shield the heat from the heat source 608 from other components of the electronic device to avoid damage due to hot spot formation by the heat source 608.

Similarly, the composite film 100 depicted in FIG. 10 includes an arrangement of conductive material layer 102 and the polymer aerogel layer 104, according to an example of the present subject matter. In an example of the present subject matter, the composite film 100 may include the metal layer 604-2 disposed beneath the polymer aerogel layer 104. As described earlier, the polymer aerogel layer 104 and the metal layer 604-2 may be attached through the adhesive layer 606-2. Further, the graphene layer 602-4 may be disposed beneath the metal layer 604-2, such that the heat generated by the heat source 608 is dissipated by the graphene layer 602-4 and the metal layer 604-2.

The composite film 100 as described in reference of FIG. 1 to FIG. 10 may be applied to various electronic devices to provide effective heat dissipation and to shield users and components of the electronic device from hot spots and damage attributed thereto.

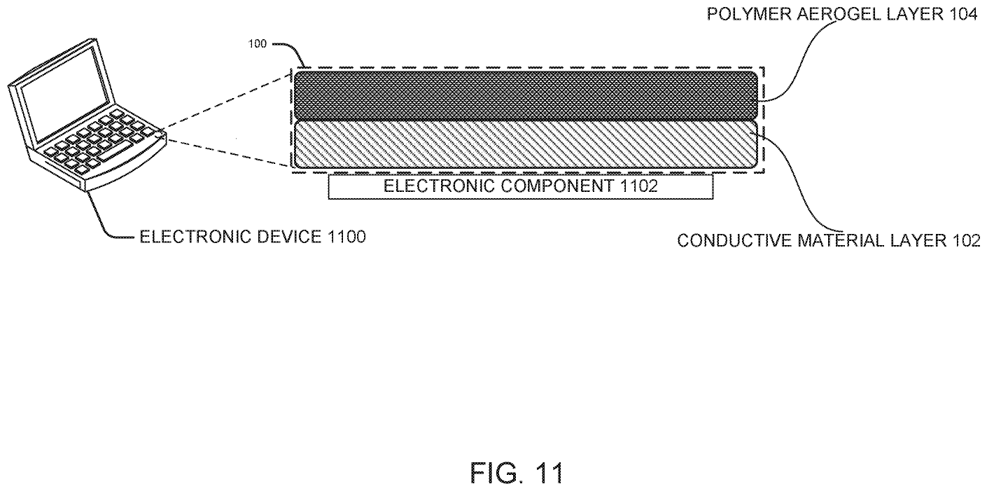

FIG. 11 depicts an electronic device 1100, implementing the composite film 100, according to an example of the present subject matter. The electronic device 1100 includes an electronic component 1102 which may generate heat during operation. The composite film 100 may be disposed over or attached to the electronic component 1102 to dissipate heat generated by the electronic component 1102. In an example of the present subject matter, the composite film 100 may include at least one conductive material layer 102 abutting one side of at least one polymer aerogel layer 104. The conductive material layer 102 may absorb heat from the electronic component 1102 and dissipate the heat to the surroundings while the polymer aerogel layer 104 may shield other components and users of the electronic device 1100 from hot spots created by the electronic component 1102.

In an example of the present subject matter, the conductive material layer 102 may include different layers, such graphene layers, graphite layers and metal layers. In an example, the conductive material layer 102 may include a first graphite layer and a second graphite layer. Further, the first graphite layer and the second graphite layer may also include a metal layer sandwiched between the first graphite layer and the second graphite layer.

The electronic device 1100 may be any device that may include electronic components that generate heat during operation, such as a laptop, a desktop, a tablet, a smartphone, a LED television (TV), a LCD TV, a tablet, a phablet, a camera, a gaming unit, and a printer. Further, the electronic component 1102 may include, but is not limited to, a capacitor, a resistor, an inductor, a processor, any integrated circuit, such as a microprocessor, a microchip, an amplifier and timer, a transformer, a relay, a motor, or other heat-generating components.

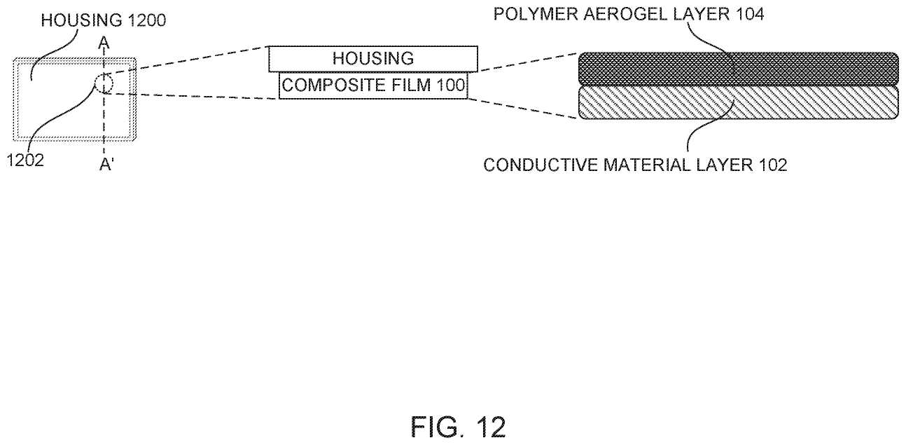

FIG. 12 depicts a housing 1200, implementing the composite film 100, according to an example of the present subject matter. In an example, the housing 1200 may be part of an electronic device and may house different electronic components which may generate heat during their operation. For example, the housing 1200 may be of a cellular phone and may house components of the cellular phone, such as a processor, a battery, a screen, and others. Such housing 1200 of the cellular phone may utilize the composite film 100 for heat dissipation.

In an example of the present subject matter, the composite film 100 may be disposed in an surface 1202 of the housing 1200. The surface 1202 of the housing 1200 may be in proximity with an electronic component that may generate heat during operation. In an example, the composite film 100 may be interface with the surface 1202 through the adhesive layer 606-3, as described above. A cross section view of the surface 1202 along the line A-A′ is depicted to show the placement of the composite film 100 on the housing 1200. In an example of the present subject matter, the composite film may include at least one conductive material layer 102 and at least one polymer aerogel layer 104 disposed over the at least one conductive material layer 102.

As described earlier, the composite film 100 may include multiple conductive material layers 102, including layers of graphene, copper, natural graphite, gold, synthetic graphite, aluminum, and silver.

Although examples for the present disclosure have been described in language specific to structural features, it would be understood that the appended claims are not necessarily limited to the specific features described. Rather, the specific features are disclosed and explained as examples of the present disclosure.

I/We claim:

1. A composite film for heat dissipation comprising:
at least one conductive material layer for thermal conduction of heat; and
at least one polymer aerogel layer disposed over the at least one conductive material layer to provide insulation from the heat.

2. The composite film as claimed in claim 1, wherein the at least one conductive material layer comprises:
a first graphene layer;
a second graphene layer; and
at least one metal layer sandwiched between the first graphene layer and the second graphene layer.

3. The composite film as claimed in claim 1 further comprising at least one other conductive layer disposed over the at least one polymer aerogel layer, wherein the polymer aerogel layer is sandwiched between the at least one conductive material layer and the at least one other conductive material layer.

4. The composite film as claimed in claim 3, wherein the at least one other conductive material layer comprises:
a third graphene layer;
a fourth graphene layer; and
at least one other metal layer sandwiched between the third graphene layer and the fourth graphene layer.

5. The composite film as claimed in claim 1 further comprising an adhesive layer disposed between the at least one conductive material layer and the polymer aerogel layer.

6. The composite film as claimed in claim 1, wherein the polymer aerogel layer comprises one of phenolics, polyurethanes, polyimides, and polyamides.

7. An electronic device comprising:
an electronic component;
a composite film provided over the electronic component, wherein the composite film comprises:
conductive material layers disposed over the electronic component to dissipate heat; and
a polymer aerogel layer disposed over the conductive material layers, wherein one side of the polymer aerogel layer abuts a conductive material layer from amongst the conductive material layers.

8. The electronic device as claimed in claim 7, wherein the composite film further comprises an adhesive layer disposed on another side of the polymer aerogel layer.

9. The electronic device as claimed in claim 7, wherein the composite film further comprises other conductive material layers disposed over another side of the polymer aerogel layer.

10. The electronic device as claimed in claim 9, wherein the composite film further comprises an adhesive layer disposed over the other conductive material layers, wherein the adhesive layer comprises one of isocyanate based polymers, epoxies, acrylics, hot melt adhesives, ethylene-vinyl acetate (EVA) copolymers, polyamides, polyolefins, styrene copolymers, polyester, polyurethane and rubber.

11. The electronic device as claimed in claim 7, wherein the conductive material layers comprises at least one of a graphene layer, a graphite layer and a synthetic graphite layer.

12. The electronic device as claimed in claim 7, wherein the conductive material layers comprises;
a first graphite layer;
a second graphite layer; and
at least one metal layer sandwiched between the first graphite layer and the second graphite layer.

13. The electronic device as claimed in claim 7, wherein the polymer aerogel layer is formed of one of phenolics, polyurethanes, polyimides, and polyamides.

14. A housing of an electronic device comprising:
a composite film disposed on a surface of the housing, wherein the composite film comprises:
a conductive material layer interfacing the surface of the housing for thermal conduction of heat; and
a polymer aerogel layer disposed over the conductive material layer to provide insulation from the heat.

15. The housing as claimed in claim 14, wherein the polymer aerogel layer is formed of one of phenolics, polyurethanes, polyimides, and polyamides.
